(19) United States
(12) Patent Application Publication
(10) Pub. No.: US 2026/0068690 A1
(43) Pub. Date: Mar. 5, 2026

(54) FILL SHAPE OPTIMIZATION FOR SUBSTRATE BONDING

(71) Applicant: Tokyo Electron Limited, Tokyo (JP)

(72) Inventors: David Power, Albany, NY (US); David Conklin, Saratoga Springs, NY (US)

(21) Appl. No.: 18/824,470

(22) Filed: Sep. 4, 2024

(51) Int. Cl. H01L 21/48; H01L 21/66; H01L 23/498

(52) U.S. Cl. CPC H01L 21/485

(57) ABSTRACT

A method of forming a patterned metal layer on a substrate includes identifying at least one distortion zone in a design pattern of metal structures causing a Z-direction displacement of the substrate, inserting metal fill shapes as a fill pattern into the design pattern to reduce the Z-direction displacement in the at least one distortion zone, and forming the metal structures and the metal fill shapes on the substrate as the patterned metal layer. The method may further include calculating bond strength of the substrate based on the design pattern and the fill pattern and adjusting surface area of the metal fill shapes to increase the bond strength. A bonded substrate structure may then be formed by directly bonding a dielectric material of the patterned metal layer of the substrate to an additional substrate.

### TECHNICAL FIELD

The present invention relates generally to substrate bonding processes, and, in particular embodiments, to systems and methods for bonding substrate using fill shapes inserted into a design pattern.

### BACKGROUND

In the semiconductor industry, technological advancement has historically been achieved by scaling down generational technology nodes to ever smaller features and critical dimensions. In recent years, due to a variety of factors including increasing cost and complexity of nodes in nanometer ranges, heterogenous integration of different semiconductor parts into advanced packages has become an increasingly important economic factor in the semiconductor industry. In particular, a need for ever greater numbers of transistors in applications that push performance limits, such as high-performance computing, artificial intelligence (AI)/machine learning (ML), machine vision, and autonomous vehicles and robots, among others, has made such advanced heterogenous packages more economically important. The economic advantages of heterogenous integration can include the ability to combine or mix semiconductor parts from different technology nodes into a single package. In this manner, the complexity or scope of portions of the single heterogenous package that utilize the latest but most resource-intensive technology nodes, e.g., 7 nm or 3 nm nodes, can be reduced or minimized, which can lead to overall economic optimization.

The semiconductor industry has embraced 3D packaging to enable hybrid devices, such as that stack bonded die together and mix different technology nodes in a single final product for economic benefits. Such 3D ICs are often fabricated using substrate bonding processes that produce multiple 3D ICs or chips in a single operation, which can then be sliced apart from the bonded wafer structure. Bonding processes may be wafer-to-wafer (W2W), die-to-wafer (D2W), or die-to-die (D2D), which involve bonding an entire wafer to another entire wafer, bonding at least one die to an entire wafer, or bonding at least one die to another die, respectively.

One type of bonding process is fusion bonding, where two substrate surfaces are brought into intimate contact at room temperature and then annealed at higher temperatures (e.g., 800-1200° C.) to form strong covalent bonds. The annealing temperature may be lowered using surface activation techniques (e.g., exposing the bonding surface to plasma). Surface activation may allow strong covalent bonds to be formed at annealing temperatures less than 400° C., for example. Fusion bonding may be used in a variety of applications, including silicon-on-insulator (SOI) fabrication, microelectromechanical devices (MEMS), nanoelectromechanical devices (NEMS), and others. Another similar type of bonding process is known as hybrid bonding and combines aspects of fusion bonding with metal-to-metal bonding. Specifically, hybrid bonding simultaneous bonds dielectric materials and metal materials, such as interconnects. Hybrid bonding may be used in applications where electrical contact between the two wafers is desired, such as for three-dimensional integration (3DI) in advanced packaging applications.

### SUMMARY

In accordance with an embodiment of the invention, a method of forming a patterned metal layer on a substrate includes identifying at least one distortion zone in a design pattern of metal structures causing a Z-direction displacement of the substrate, inserting metal fill shapes as a fill pattern into the design pattern to reduce the Z-direction displacement in the at least one distortion zone, and forming the metal structures and the metal fill shapes on the substrate as the patterned metal layer.

In accordance with another embodiment of the invention, a method of forming a bonded substrate structure includes calculating bond strength of a substrate based on a design pattern of metal structures and a fill pattern of metal fill shapes, adjusting surface area of the metal fill shapes to increase the bond strength, forming the metal structures and the metal fill shapes on the substrate as a patterned metal layer, and directly bonding a dielectric material of the patterned metal layer of the substrate to an additional substrate to form the bonded substrate structure.

In accordance with still another embodiment of the invention, a method of forming a bonded substrate structure includes identifying at least one distortion zone in a design pattern of metal structures causing a Z-direction displacement of a substrate, inserting metal fill shapes as a fill pattern into the design pattern to reduce the Z-direction displacement in the at least one distortion zone, calculating bond strength of the substrate based on the design pattern and the fill pattern, adjusting surface area of the metal fill shapes to increase the bond strength, forming the metal structures and the metal fill shapes on the substrate as a patterned metal layer, and directly bonding a dielectric material of the patterned metal layer of the substrate to an additional substrate to form the bonded substrate structure.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example method of forming a patterned metal layer on a substrate where a fill pattern is inserted into a design pattern to reduce Z-direction displacement of the substrate in accordance with embodiments of the invention;

FIG. 2 illustrates an example method of forming a bonded substrate structure where a fill pattern is inserted into a design pattern to maximize bond strength of the substrate in accordance with embodiments of the invention;

FIG. 3 illustrates an example method of forming a bonded substrate structure where a fill pattern is inserted into a design pattern to reduce Z-direction displacement and to maximize bond strength of the substrate in accordance with embodiments of the invention;

FIG. 4 illustrates an example substrate the that includes a design pattern for which distortion zones have been identified in a Z-displacement map based on the Z-direction displacement gradient of the substrate in accordance with embodiments of the invention;

FIG. 5 illustrates an example substrate the that includes a design pattern and a fill pattern and a corresponding corrected Z-displacement map reducing distortion of the substrate in accordance with embodiments of the invention;

FIG. 6 illustrates an example substrate configured to be bonded to another substrate, the substrate including a design pattern and a fill pattern with larger fill shapes in accordance with embodiments of the invention; and

FIG. 7 illustrates an example substrate configured to be bonded to another substrate, the substrate including a design pattern and a fill pattern with larger fill shapes in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

In applications such as 3DI for advanced packaging, one or both of the substrates being bonded together may have a design pattern that will be formed prior to bonding and be exposed at the bonding surface (e.g., bond pads, for example). Conventional methodology uses simplistic fill shapes (e.g., dummy structures of the same material and size as the design features) that are inserted into the design pattern to help with uniformity during certain processes, such as etching and chemical mechanical polishing (CMP). For example, conventional fill shape insertion techniques might insert fill shapes to increase the metal density of the pattern to meet a general metal density rule, such as between 40% and 80%.

The inventors have observed that characteristics of the design pattern also affect the quality of the bonding process. For example, the design pattern exerts stress on the substrate that can affect substrate flatness. When the design pattern includes local differences in topography and topology, stress can be applied unevenly across the substrate resulting in localized displacement in the Z-direction. Additionally, some layers of dielectric are intentionally stressed (e.g., compressively). Since the design pattern structures also stress the substrate, the specific configuration of the design pattern also affects the balance the stress in the substrate, which may be a multi-layer problem through the back-end-of-line stack. Further, in the case of hybrid bonding, the amount of surface area of the design pattern (metal) influences the bond strength between the substrates. However, to this point, conventional fill shape insertion techniques have failed to consider the complexities of bonding processes.

In accordance with embodiments herein described, the invention proposes a method that inserts metal fill shapes into empty spaces between metal structures of a design pattern (e.g., between bond pads). The metal fill shapes are made of the same material as the bond pads and are added to optimize one or both of the Z-direction displacement of the substrate (distortion) and the bond strength when the substrate is configured to be directly bonded to an additional substrate. For embodiments that co-optimize both Z-direction displacement and bond strength, a fill pattern may be determined that optimizes the total benefit achieved by the fill pattern.

The embodiment fill insertion methods described herein may provide various advantages over conventional fill insertion techniques by considering additional factors related to bonding processes, such as Z-direction displacement and bond strength. For example, the embodiment fill insertion methods may represent a more sophisticated and tailored approach to fill shape insertion, such as in the context of substrate bonding (e.g., W2W, W2D, or D2D bonding), which may advantageously improve the quality and reliability of bonded semiconductor devices.

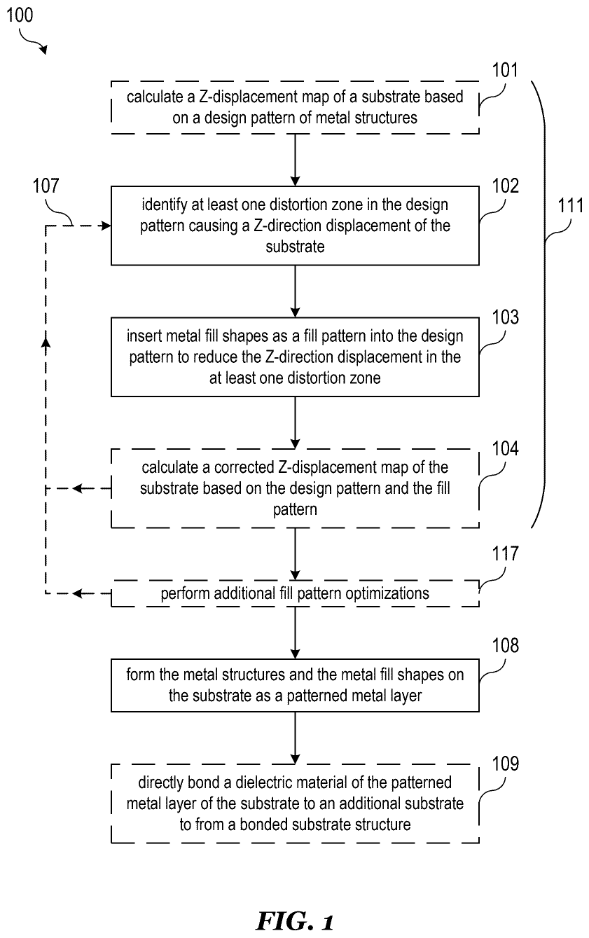

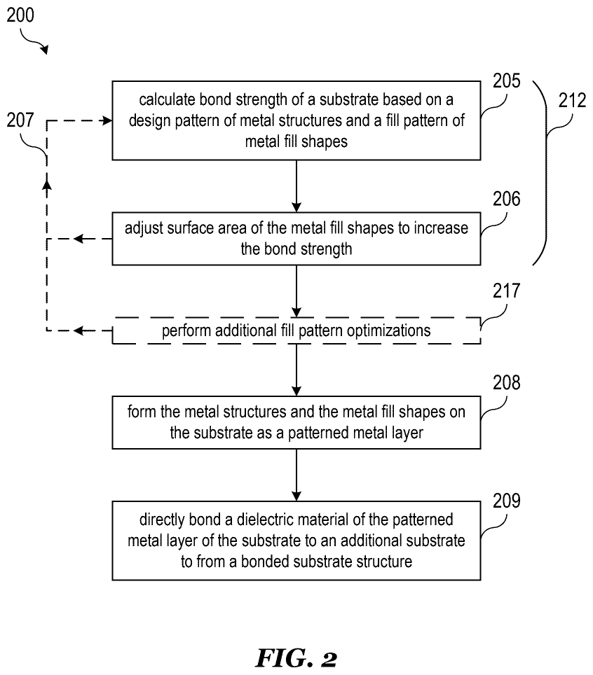

FIG. 1 illustrates an example method of forming a patterned metal layer on a substrate where a fill pattern is inserted into a design pattern to reduce Z-direction displacement of the substrate in accordance with embodiments of the invention. The method of FIG. 1 may be combined with other methods and performed using the systems and apparatuses as described herein. For example, the method of FIG. 1 may be combined with any of the embodiments of FIGS. 2-7. Although shown in a logical order, the arrangement and numbering of the steps of FIG. 1 are not intended to be limited. The method steps of FIG. 1 may be performed in any suitable order or concurrently with one another as may be apparent to a person of skill in the art.

Referring to FIG. 1, a method 100 of forming a patterned metal layer on a substrate includes a distortion zone identification step 102 during which at least one distortion zone is identified in a design pattern of metal structures. In particular, the metal structures in the design pattern can exert stresses on the substrate causing a Z-direction displacement of the substrate. The localized displacement of the substrate depends on the various properties of the design pattern, such as size, shape, density, and location of the metal structures in addition to other factors such as material composition of the metal structures and underlying layers, temperature, crystal structure (or lack thereof), and others.

The method 100 seeks to address variations in pattern density that lead to changes in the substrate stress (e.g., the die stress) by balancing the stresses of the design pattern to reduce substrate distortion. Stress on the substrate can cause dislocations in the crystal structure of the metal layer, such as lattice dislocations and thermal dislocations (which may be caused by thermal stress). In addition to stress from the metal structures of the design patter, stress may also be applied to the substrate from dielectric layers of the substrate (e.g., compressive stress), that can cause the substrate to deform or buckle if left unbalanced. For example, the dielectric stack and the metal stack may have different stresses. In various embodiments, the method 100 considers other materials and layers of the substrate along with the design pattern and balances out stress in the substrate to reduce substrate distortion.

Each distortion zone is a region of the substrate that is identified as causing at least some Z-direction displacement of the substrate. A distortion zone may be identified using various criteria related to the Z-direction displacement of the substrate. That is, regions of the substrate that are not identified as meeting the criteria do not have sufficient Z-direction displacement to be considered part of a distortion zone. In various embodiments, the criteria includes a threshold displacement value, such as a deviation of the substrate height from a reference height (e.g., identified as zero displacement, for example). In one embodiment, the reference height is the lowest point of the distorted substrate. In another embodiment, the reference height is the height of the substrate before any distortion occurs (i.e., a flat substrate, which may be an idealized state). In other embodiments, the reference height may be another height value, such as the average height after distortion, the median height after distortion, and others.

The criteria may be used to identify multiple distortion zones, such as regions that adhere to certain ranges of criteria, such as displacement values, displacement gradient, etc. Additional metal fill shapes may then be inserted into the fill pattern to reduce Z-direction displacement of the substrate in each distortion zones. For example, since the regions in each identified distortion zone may have some similarity, the metal fill shapes inserted in that region may also have some similarity allowing the identification of multiple distortion zones to advantageously aid in the correction of substrate distortion.

Based on the identified distortion zones, metal fill shapes are inserted as a fill pattern into the design pattern during a fill pattern insertion step 103. The inserted metal fill shapes reduce the Z-direction displacement in the distortion zones (i.e., resulting in a flatter substrate that when the design pattern did not include the fill pattern). For example, there may be a considerable “white space” area of the design pattern (e.g., 60-70% of the area) where the metal fill shapes may be inserted to manipulate the Z-direction displacement (i.e., the substrate stress) to reduce substrate distortion.

In contrast to conventional fill shape insertion techniques that do not consider the direct effects of the metal structures of the design pattern on the Z-direction displacement of the substrate, the method 100 specifically considers Z-direction displacement when identifying at least one distortion zone during the distortion zone identification step 102 and inserting metal fill shapes into the design pattern during the fill pattern insertion step 103 to reduce distortion of substrate as part of a Z-displacement minimization method 111.

The distortion zones may be identified in various ways in the distortion zone identification step 102. For example a Z-displacement map of the substrate may be calculated (e.g., simulated) based on the design pattern during a displacement calculation step 101. The distortion zones may then be identified using the Z-displacement map (e.g., by comparing each data point of the Z-displacement map to the criteria for being considered a distortion zone). Various factors may be considered when simulating the Z-direction displacement of the substrate to calculate the Z-displacement map, including calculating Z-displacement of the substrate due to thermal stress, such as when the temperature of the substrate is increased (or even decreased) during some event, such as at or near a projected operating temperature, at or near a projected processing temperature, etc. For example, the differences in properties of the materials on the substrate, such as different coefficients of thermal expansion, may cause additional stress on the substrate at different temperatures.

After the metal shapes are inserted into the fill pattern in the fill pattern insertion step 103, a corrected Z-displacement map of the substrate may be calculated based on the design pattern and the fill pattern during a corrected displacement calculation step 104. The corrected Z-displacement map may be used to determine how effective the fill pattern is at reducing the Z-direction displacement of the substrate. In some embodiments, the corrected Z-displacement map may be used to decide whether additional iterations of the Z-displacement minimization method 111 (iteration steps 107) are performed. For example, the distortion zone identification step 102, the fill pattern insertion step 103, and the corrected displacement calculation step 104 may be repeated as the iteration steps 107 until a predetermined Z-displacement criterion is satisfied before continuing the method 100.

The predetermined Z-displacement criterion may be various metrics, such as a maximum Z-displacement threshold across the substrate. When all data points of the corrected Z-displacement map are below the maximum Z-displacement threshold, the predetermined Z-displacement criterion may be considered met and the method 100 may continue. Otherwise, when one or more data points of the corrected Z-displacement map are above the maximum Z-displacement threshold, the iteration steps 107 may be performed. The predetermined Z-displacement criterion may also be based on the change in the displacement (e.g., average displacement across the substrate) between successive calculations of the corrected Z-displacement map. For example, when the displacement change is smaller than a minimum displacement delta threshold, the Z-direction displacement may be considered minimized, and the method 100 may continue. Of course many other possibilities for evaluating whether to continue the Z-displacement minimization method 111 may be apparent to those of skill in the art.

The localized topography and topology of the design pattern and the fill pattern may have effects that manifest as longer range effects. More than one Z-displacement map may be calculated during the corrected displacement calculation step 104 and/or the displacement calculation step 101. Specifically, the corrected Z-displacement map may be calculated using a certain window size (i.e., each displacement value in the Z-displacement map may be calculated by considering the stress from the design pattern in a window of a certain size surrounding each location corresponding to a displacement value). In this way, the window size may determine the effective range being considered for the data points. That is, smaller window sizes may include only short range stress effects while larger window sizes include stress effects from farther away (e.g., longer range effects).

In various embodiments, the corrected displacement calculation step 104 includes calculating multiple corrected Z-displacement maps using different window sizes. In some embodiments, the corrected displacement calculation step 104 includes calculating at least one long-range corrected Z-displacement map of the substrate based on the design pattern and the fill pattern using a first window size and also calculating a short-range corrected Z-displacement map using a second window size that is smaller than the first window size. Of course, any desired number of Z-displacement maps may be calculated with different window sizes. For example, investigating long and short range effects may provide additional information about how to insert metal fill shapes into the fill pattern to correct for distortion of the substrate.

After the fill pattern insertion step 103, other optimization steps 117 may be performed to adjust the impact of the design pattern and the fill pattern on other aspects of the substrate. For example, pattern density may be considered in addition to correcting for substrate distortion. In some applications, the substrate is configured to be bonded to another substrate. In one embodiment, the other optimization steps 117 includes calculating bond strength of the substrate based on the design pattern and the fill pattern and adjusting surface area of the metal fill shapes to increase bond strength (additional details of which are provided in the following). It should also be noted that the other optimization steps 117 may also be iterated (e.g., as part of the iteration steps 107) in some embodiments.

After the metal fill shapes of the fill pattern are optimized using the Z-displacement minimization method 111 and any other optimization steps 117, the method 100 includes a patterned metal layer formation step 108 of forming the metal structures and the metal fill shapes on the substrate as a patterned metal layer. Additionally, when the substrate is configured to be bonded to another substrate, a bonding step 109 may also be included during which a dielectric material of the patterned metal layer of the substrate is directly bonded to an additional substrate to from a bonded substrate structure. When the bonding is fusion bonding, only the dielectric material may participate in the substrate bonding. When the bonding is hybrid bonding, the metal material of the patterned metal layer may also participate in the substrate bonding.

FIG. 2 illustrates an example method of forming a bonded substrate structure where a fill pattern is inserted into a design pattern to maximize bond strength of the substrate in accordance with embodiments of the invention. The method of FIG. 2 may be combined with other methods and performed using the systems and apparatuses as described herein. For example, the method of FIG. 2 may be combined with any of the embodiments of FIGS. 1 and 3-7. Although shown in a logical order, the arrangement and numbering of the steps of FIG. 2 are not intended to be limited. The method steps of FIG. 2 may be performed in any suitable order or concurrently with one another as may be apparent to a person of skill in the art. Similarly labelled elements may be as previously described.

Referring to FIG. 2, a method 200 of forming a bonded substrate structure includes a bond strength calculation step 205 and a surface area adjustment step 206 that together form a bond strength maximization method 212. For example, a patterned metal layer may include dielectric material and metal material. Depending on the specifics of the pattern and the bonding type, the dielectric bond may be stronger or the metal bond may be stronger. This may affect the size and distribution of the fill shapes used to achieve maximum bond strength.

During the bond strength calculation step 205, bond strength of a substrate (i.e., a substrate configured to be bonded to an additional substrate) is calculated based on a design pattern of metal structures and a fill pattern of metal fill shapes. The type of bonding is considered during the bond strength calculation step 205. For example, if the type of bonding is fusion bonding, then the bond strength is calculated based on the dielectric material of a patterned metal layer. Alternatively, if the type of bonding is hybrid bonding, then the bond strength is calculated based on both the dielectric material and the metal material of the patterned metal layer.

During the surface area adjustment step 206 the surface area of the metal fill shapes of the fill pattern are adjusted to increase the bond strength. For example, when the substrate is configured to be directly bonded to an additional substrate using a fusion bonding process, adjusting the surface area of the metal fill shapes includes decreasing the surface area of the metal fill shapes (which in turn increases the surface area of the dielectric material, increasing the bond strength). However, metal bonds may be stronger than dielectric bonds. So, when the substrate is configured to be directly bonded to an additional substrate using a hybrid bonding process, adjusting the surface area of the metal fill shapes includes increasing the surface area of the metal fill shapes, which increases the proportion of the bonds that are metal bonds and increases the bond strength.

The bond strength may be locally calculated in some embodiments. For example, the bond strength calculation step 205 may include calculating localized bond strength in windows across the substrate. The surface area of the metal fill shapes may then be adjusted during the surface area adjustment step 206 for each of the windows to increase uniformity of the bond strength across the substrate.

Similar to the Z-displacement minimization method 111 in the method 100 of FIG. 1, the bond strength maximization method 212 may be repeated as iteration steps 207 to further modify the bond strength before continuing the method 200. As before, other optimization steps 217 may be performed in addition to the bond strength maximization method 212 (which may also be iterated). For example, pattern density may be optimized and/or distortion of the substrate may be addressed using a Z-displacement minimization method. Of course, other effects may also be optimized during the other optimization steps 217 as well.

After the bond strength maximization method 212, the metal structures of the design patter and the metal fill shapes of the fill pattern are formed on the substrate as a patterned metal layer during a patterned metal layer formation step 208. The dielectric material (and the metal material when the bonding type is hybrid bonding) of the patterned metal layer is then directly bonded to an additional substrate during a bonding step 209. In addition to the two types of direct bonding (fusion bonding and hybrid bonding), the types of substrates may also vary. In one embodiment, the substrate is a die and the additional substrate is a wafer (D2W bonding). In another embodiment, the substrate is a wafer and the additional substrate is an additional wafer (W2W bonding). Both substrates may also be dies (D2D bonding), for example.

It should be noted that here and in the following a convention has been adopted for brevity and clarity wherein elements adhering to the pattern [x08] where ‘x’ is the figure number may be related implementations of a patterned metal layer formation step in various embodiments. For example, the patterned metal layer formation step 208 may be similar to the patterned metal layer formation step 108 except as otherwise stated. An analogous convention has also been adopted for other elements as made clear by the use of similar terms in conjunction with the aforementioned numbering system.

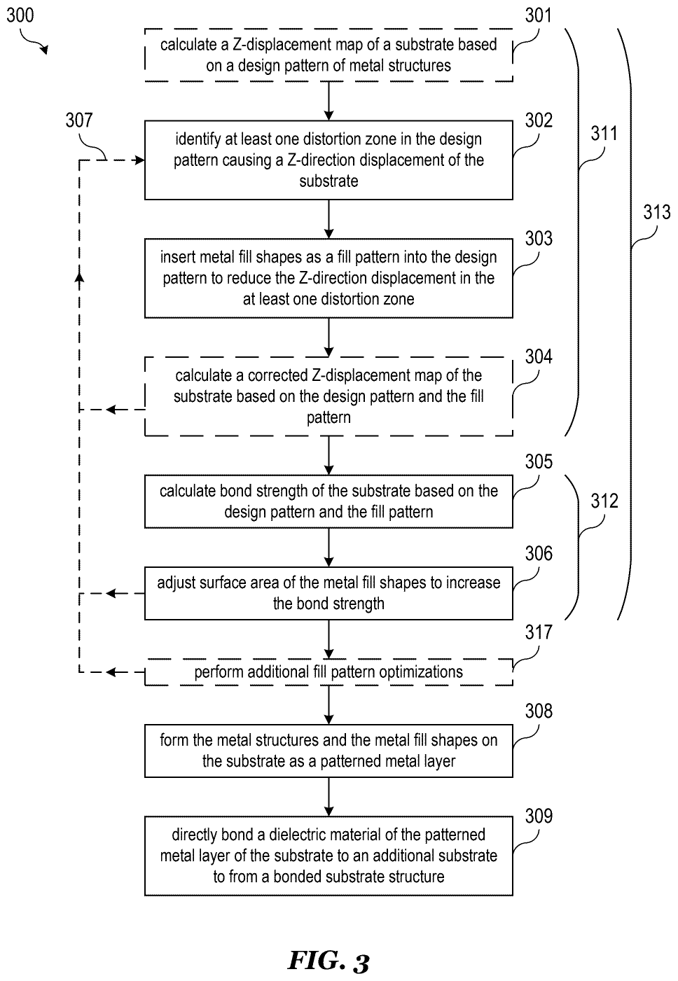

FIG. 3 illustrates an example method of forming a bonded substrate structure where a fill pattern is inserted into a design pattern to reduce Z-direction displacement and to maximize bond strength of the substrate in accordance with embodiments of the invention. The method of FIG. 3 may be combined with other methods and performed using the systems and apparatuses as described herein. For example, the method of FIG. 3 may be combined with any of the embodiments of FIGS. 1-2 and 4-7. Although shown in a logical order, the arrangement and numbering of the steps of FIG. 3 are not intended to be limited. The method steps of FIG. 3 may be performed in any suitable order or concurrently with one another as may be apparent to a person of skill in the art. Similarly labelled elements may be as previously described.

Referring to FIG. 3, a method 300 forming a bonded substrate structure includes both a Z-displacement minimization method 311 and a bond strength maximization method 312 as part of a co-optimization method 313. Various steps of the method 300 may be similar to previously described methods. For example, the method 300 is a specific example of the method 100 of FIG. 1 that includes bond strength maximization as part of the other optimization steps 117. Similarly, the method 300 is a specific example of the method 200 of FIG. 2 that includes Z-displacement minimization as part of the other optimization steps 217.

As before, the Z-displacement minimization method 311 includes a distortion zone identification step 302 and a fill pattern insertion step 303. Initially, a Z-displacement map may be calculated in a displacement calculation step 301 and a corrected Z-displacement map may be calculated after inserting metal fill shapes to determine the degree that the Z-direction displacement has been corrected. The bond strength maximization method 312 includes a bond strength calculation step 305 and a surface area adjustment step 306. The steps of the bond strength maximization method 312 may be performed after the fill pattern has been added in the fill pattern insertion step 303, but this does not have to be the case. For example, some or all of the optimization steps may be performed before adding the fill pattern in some embodiments.

Various optimization steps may be repeated to modify the fill pattern as iteration steps 307 before continuing the method 300. For example, the Z-displacement minimization method 311 may be repeated as part of the iteration steps 307 until a predetermined Z-direction displacement criterion has been met. Similarly, the bond strength maximization method 312 may also be repeated as part of the iteration steps 307 along with any other optimization steps 317 that are included, if desired.

Since trade-offs may exist between optimizing the Z-direction displacement and the bond strength, the method 300 may consider a co-optimization criterion (or criteria) to dictate the relationship between the parameters (as well as between any other included optimizations). For example, each parameter may have separate target criteria, but one parameter may take priority over another parameter in the event that the separate criteria cannot be simultaneously achieved. Whether substrate distortion or bond strength has priority may depend on the size of the substrate. In one embodiment, the substrate is a die (e.g., a relatively small die) and a predetermined co-optimization criterion prioritizes increasing bond strength is over reducing Z-direction displacement. In other embodiments, the substrate is a wafer (or a relatively large die) and a predetermined co-optimization criterion prioritizes reducing Z-direction displacement over increasing bond strength.

After the fill pattern has been inserted and optimized during the co-optimization method 313, the metal structures of the design patter and the metal fill shapes of the fill pattern are formed on the substrate as a patterned metal layer during a patterned metal layer formation step 308. The dielectric material (and the metal material when the bonding type is hybrid bonding) of the patterned metal layer is then directly bonded to an additional substrate during a bonding step 309. As before, the bonding process may be a fusion bonding process or a hybrid bonding process (which may affect aspects of optimization, such as surface area adjustment during the bond strength maximization method 312).

The method 300 allows for customization based on various factors, such as die size. For smaller dies, optimizing for bond strength may be prioritized, while for larger dies, minimizing Z-displacement may be prioritized due to the increased potential for warpage. Of course, the same principle may apply when the substrate is a wafer as for a larger die making Z-displacement a higher priority.

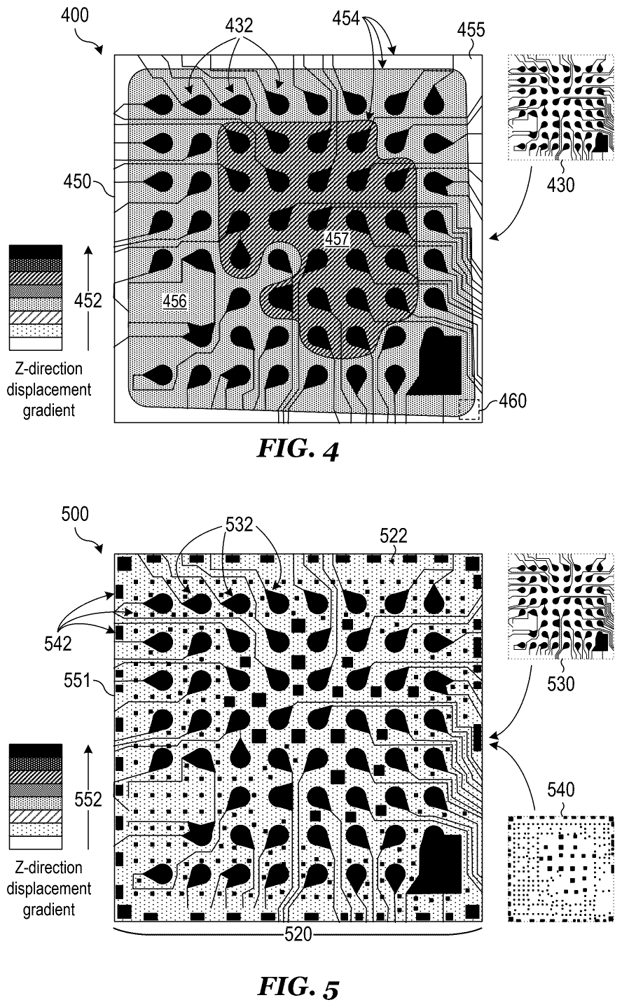

FIG. 4 illustrates an example substrate that includes a design pattern for which distortion zones have been identified in a Z-displacement map based on the Z-direction displacement gradient of the substrate in accordance with embodiments of the invention. The substrate of FIG. 4 may be a specific example of substrates discussed in reference to example methods described herein, such as the method of FIG. 1, for example.

Referring to FIG. 4, a substrate 400 includes a design pattern 430 of metal structures 432 (e.g., bond pads) that have varying shapes, sizes, orientation, and pattern density. Although schematically illustrated as a die in this example, the substrate 400 may be any suitable substrate in any suitable form factor (i.e., a die or wafer in any desired size). In this specific example, the design pattern 430 has a high density of bond pads and a lower density around them. This leads to substrate distortion in the Z-direction that varies across the substrate 400.

A Z-displacement map 450 is superimposed over the design pattern 430 of the substrate 400 to show distortion zones 454 indicating regions of distortion in the Z-direction caused by the design pattern 430. For example, the Z-displacement map 450 may be calculated based on the design pattern 430 using windows 460 of a certain size, as previously described.

Each of the distortion zones 454 may include regions of the substrate that are subjected to similar distortion effects (such as a similar displacement from a reference substrate height or a similar displacement gradient). In this specific example, the criteria used to identify the distortion zones 454 is the gradient of the Z-direction displacement 452. Three distortion zones have been identified that each correspond to a specific gradient condition, but of course more distortions zones or fewer distortion zones could be identified. Specifically, a low distortion zone 455 has been identified on the edges of the substrate 400, a low-high distortion zone 457 has been identified in the central region of the substrate 400, and a medium-high distortion zone 456 has been identified therebetween.

Within the low distortion zone 455, the Z-direction displacement 452 of the substrate 400 may change relatively little (i.e., a low displacement gradient). In contrast, the Z-direction displacement 452 of the substrate 400 may change rapidly in the low-high distortion zone low-high distortion zone 457, such as from little or no displacement between the metal structures 432 to at or near the maximum displacement at the metal structures 432 (i.e., a low-high displacement gradient). The displacement gradient in the medium-high distortion zone 456 may be an intermediate gradient, where distortion changes between medium displacement values to high displacement values (i.e., a medium-high displacement gradient).

The Z-direction displacement of the distortion zones 454 may be corrected for (i.e., the substrate 400 may be flattened out) by inserting metal fill shapes as part of a fill pattern, such as using methods already discussed. For example, the distortion zones 454 may be corrected by considering the similarities in the Z-direction displacement for a given zone. Metal fill shapes may be inserted where there are not metal structures 432 of the design pattern 430 and the characteristics of the metal fill shapes may be determined by the criteria used to identify the respective zone.

FIG. 5 illustrates an example substrate that includes a design pattern and a fill pattern and a corresponding corrected Z-displacement map reducing distortion of the substrate in accordance with embodiments of the invention. The substrate of FIG. 5 may be a specific example of substrates discussed in reference to example methods described herein, such as the method of FIG. 1, for example. Similarly labelled elements may be as previously described.

Referring to FIG. 5, a substrate 500 includes a design pattern 530 of metal structures 532 (e.g., bond pads) and a fill pattern 540 of metal fill shapes 542 (e.g., dummy bond pads). The substrate 500 is similar to the substrate 400 of FIG. 4, but now has the fill pattern 540 inserted into the design pattern 530. A corrected Z-displacement map 551 is superimposed over the design pattern 530 and the fill pattern 540 and schematically shows a substantially uniform Z-direction displacement gradient. That is, in this schematic example, the fill pattern 540 has corrected the Z-direction displacement 552 to avoid large and non-uniform gradients in the Z-direction displacement of the substrate 500 resulting in a flatter substrate.

Of course, at the stage that the corrected Z-displacement map 551 is calculated, the metal structures 532 of the design pattern 530 and the metal fill shapes 542 of the fill pattern 540 have not yet been fabricated. After the corrected Z-displacement map 551 is verified to meet the desired predetermined Z-displacement criterion, the design pattern 530 and the fill pattern 540 may be formed on the substrate 500 (i.e., an actual physical substrate) as a patterned metal layer 520 that includes a dielectric material 522 between the metal material of the metal structures 532 and the metal fill shapes 542.

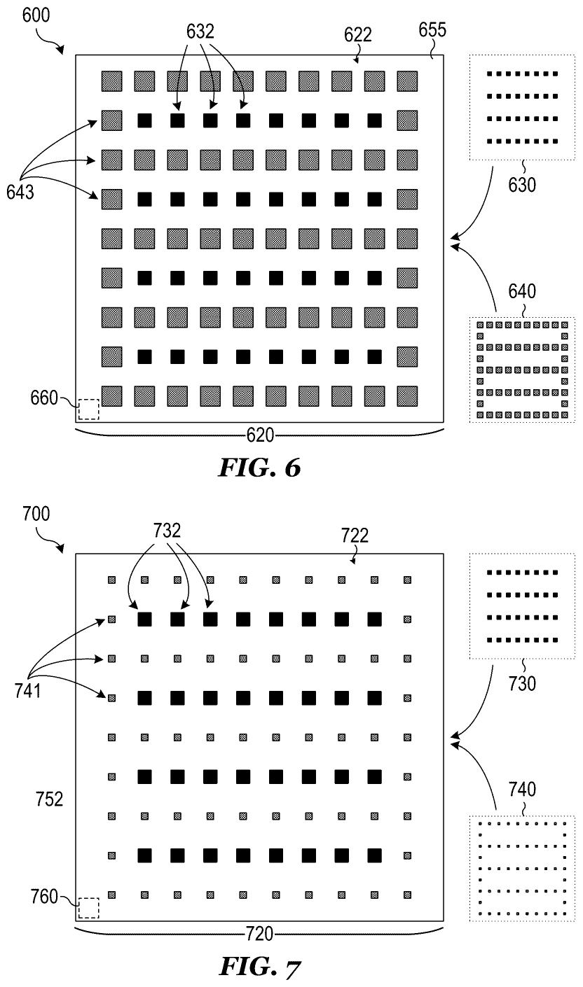

FIG. 6 illustrates an example substrate configured to be bonded to another substrate, the substrate including a design pattern and a fill pattern with larger fill shapes in accordance with embodiments of the invention. The substrate of FIG. 6 may be a specific example of substrates discussed in reference to example methods described herein, such as the method of FIG. 2, for example. Similarly labelled elements may be as previously described.

Referring to FIG. 6, a substrate 600 includes a design pattern 630 of metal structures 632 (e.g., bond pads) and a fill pattern 640 of larger fill shapes 643 (i.e., metal fill shapes, such as dummy bond pads, that are larger than the metal structures 632). The substrate 600 may represent a substrate that is configured to be bonded to an additional substrate and that has been optimized to increase (e.g., maximize) the bond strength of a bonding process. For example, the substrate 600 may be configured to be bonded to an additional substrate using a hybrid bonding process that includes metal bonding from the metal structures 632 and the larger fill shapes 643. The bond strength may be calculated in various ways for the design pattern 630 and the fill pattern 640. In one embodiment, the total bond strength is calculated. In some embodiments, localized bond strength is calculated using windows 660 of a certain size.

The larger fill shapes 643 have increased surface area compared to metal fill shapes that match the size of the metal structures 632, which may be used by conventional fill insertion techniques. The bond strength may vary depending on the properties of the materials involved for both metal bonds (metal material of a patterned metal layer 620 bonded to material, such as metal material, of the additional substrate) and dielectric bonds (a dielectric material 622 of the patterned metal layer 620 bonded to material, such as dielectric material, of the additional substrate). In various embodiments, the bond strength of the metal bonds is stronger than the bond strength of the dielectric bonds, such as when the metal is copper. In this case, increasing the surface area of the fill shapes to generate the fill pattern 640 of the larger fill shapes 643 increases the bond strength.

FIG. 7 illustrates an example substrate configured to be bonded to another substrate, the substrate including a design pattern and a fill pattern with larger fill shapes in accordance with embodiments of the invention. The substrate of FIG. 7 may be a specific example of substrates discussed in reference to example methods described herein, such as the method of FIG. 2, for example. Similarly labelled elements may be as previously described.

Referring to FIG. 7, a substrate 700 includes a patterned metal layer 720 with a design pattern 730 of metal structures 732 (e.g., bond pads) and a fill pattern 740 of smaller fill shapes 741 (i.e., metal fill shapes, such as dummy bond pads, that are smaller than the metal structures 732). The substrate 700 may represent a substrate that is configured to be bonded to an additional substrate and that has been optimized to increase (e.g., maximize) the bond strength of a bonding process. In contrast to the substrate 600 in the example of FIG. 6, the substrate 700 may be configured to be bonded to an additional substrate using a fusion bonding process that does not include metal bonding (only dielectric bonds of a dielectric material 722 of the patterned metal layer 720 bond to material, such as dielectric material, of the additional substrate). As before, the bond strength may be calculated in various ways including localized bond strength calculated using windows 760 of a certain size.

The smaller fill shapes 741 have decreased surface area compared to metal fill shapes that match the size of the metal structures 732, which may be used by conventional fill insertion techniques. Since the fusion bonding process does not include metal bonds, the smaller fill shapes 741 do not contribute to the bond strength. Thus, decreasing the surface area of the smaller fill shapes 741 relative to the metal structures 732 increases the bond strength of the fusion bonding process. It should also be noted that a similar approach of decreasing the surface area of fill shapes relative to the metal structures 732 of the design pattern 730 may also apply to a hybrid bonding process when the metal bonds are weaker than the dielectric bonds.

Additionally, the size of the smaller fill shapes 741 may be determined based on other factors as well as bond strength (which may be why the fill shapes are not simply removed to maximize bond strength). For example, other benefits may be achieved by including the smaller fill shapes 741, such as improved uniformity of the patterned metal layer 720 for subsequent processes as well as decreased substrate distortion, etc.

Example embodiments of the invention are summarized here. Other embodiments can also be understood from the entirety of the specification as well as the claims filed herein.

Example 1. A method of forming a patterned metal layer on a substrate, the method including: identifying at least one distortion zone in a design pattern of metal structures causing a Z-direction displacement of the substrate; inserting metal fill shapes as a fill pattern into the design pattern to reduce the Z-direction displacement in the at least one distortion zone; and forming the metal structures and the metal fill shapes on the substrate as the patterned metal layer.

Example 2. The method of example 1, further including: directly bonding a dielectric material of the patterned metal layer of the substrate to an additional substrate to from a bonded substrate structure.

Example 3. The method of example 2, further including: calculating bond strength of the substrate based on the design pattern and the fill pattern; and adjusting surface area of the metal fill shapes to increase bond strength before forming the patterned metal layer.

Example 4. The method of one of examples 1 to 3, further including: calculating a Z-displacement map of the substrate based on the design pattern, the at least one distortion zone being identified using the Z-displacement map; calculating a corrected Z-displacement map of the substrate based on the design pattern and the fill pattern; and repeating the steps of identifying at least one distortion zone, inserting metal fill shapes, and calculating the corrected Z-displacement map until a predetermined Z-displacement criterion is satisfied before forming the metal structures and the metal fill shapes on the substrate.

Example 5. The method of example 4, where repeating the steps further includes: calculating at least one long-range corrected Z-displacement map of the substrate based on the design pattern and the fill pattern using a first window size, the corrected Z-displacement map being a short-range corrected Z-displacement map calculated using a second window size smaller than the first window size.

Example 6. The method of one of examples 4 and 5, where calculating the Z-displacement map and calculating the corrected Z-displacement map include calculating Z-displacement of the substrate due to thermal stress.

Example 7. The method of one of examples 1 to 6, further including: inserting additional metal fill shapes in the fill pattern to reduce Z-direction displacement of the substrate in additional distortion zones of the at least one distortion zone.

Example 8. A method of forming a bonded substrate structure, the method including: calculating bond strength of a substrate based on a design pattern of metal structures and a fill pattern of metal fill shapes; adjusting surface area of the metal fill shapes to increase the bond strength; forming the metal structures and the metal fill shapes on the substrate as a patterned metal layer; and directly bonding a dielectric material of the patterned metal layer of the substrate to an additional substrate to form the bonded substrate structure.

Example 9. The method of example 8, further including: identifying at least one distortion zone in the design pattern causing a Z-direction displacement of the substrate; inserting the metal fill shapes as the fill pattern into the design pattern to reduce the Z-direction displacement in the at least one distortion zone.

Example 10. The method of one of examples 8 and 9, where calculating the bond strength includes calculating localized bond strength in windows across the substrate, and where adjusting the surface area includes adjusting the surface area of the metal fill shapes for each of the windows to increase uniformity of the bond strength across the substrate.

Example 11. The method of one of examples 8 to 10, where directly bonding the substrate to the additional substrate is a fusion bonding process, and where adjusting the surface area of the metal fill shapes includes decreasing the surface area of the metal fill shapes.

Example 12. The method of one of examples 8 to 10, where directly bonding the substrate to the additional substrate further includes directly bonding metal material of the patterned metal layer of the substrate to the additional substrate in a hybrid bonding process, and where adjusting the surface area of the metal fill shapes includes increasing the surface area of the metal fill shapes.

Example 13. The method of one of examples 8 to 12, where the substrate is a die and the additional substrate is a wafer.

Example 14. The method of one of examples 8 to 12, where the substrate is a wafer and the additional substrate is an additional wafer.

Example 15. A method of forming a bonded substrate structure, the method including: identifying at least one distortion zone in a design pattern of metal structures causing a Z-direction displacement of a substrate; inserting metal fill shapes as a fill pattern into the design pattern to reduce the Z-direction displacement in the at least one distortion zone; calculating bond strength of the substrate based on the design pattern and the fill pattern; adjusting surface area of the metal fill shapes to increase the bond strength; forming the metal structures and the metal fill shapes on the substrate as a patterned metal layer; and directly bonding a dielectric material of the patterned metal layer of the substrate to an additional substrate to form the bonded substrate structure.

Example 16. The method of example 15, further including: calculating a Z-displacement map of the substrate based on the design pattern, the at least one distortion zone being identified using the Z-displacement map; calculating a corrected Z-displacement map of the substrate based on the design pattern and the fill pattern; and repeating the steps of identifying at least one distortion zone, inserting metal fill shapes, calculating the corrected Z-displacement map, calculating the bond strength, and adjusting the surface area until a predetermined co-optimization criterion is satisfied before forming the metal structures and the metal fill shapes on the substrate.

Example 17. The method of example 16, where the substrate is a die and the additional substrate is a wafer, and where the predetermined co-optimization criterion prioritizes increasing bond strength.

Example 18. The method of example 16, where the substrate is a wafer and the additional substrate is an additional wafer, and where the predetermined co-optimization criterion prioritizes reducing Z-direction displacement.

Example 19. The method of one of examples 15 to 18, where directly bonding the substrate to the additional substrate is a fusion bonding process, and where adjusting the surface area of the metal fill shapes includes decreasing the surface area of the metal fill shapes.

Example 20. The method of one of examples 15 to 18, where directly bonding the substrate to the additional substrate further includes directly bonding metal material of the patterned metal layer of the substrate to the additional substrate in a hybrid bonding process, and where adjusting the surface area of the metal fill shapes includes increasing the surface area of the metal fill shapes.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of forming a patterned metal layer on a substrate, the method comprising:
identifying at least one distortion zone in a design pattern of metal structures causing a Z-direction displacement of the substrate;
inserting metal fill shapes as a fill pattern into the design pattern to reduce the Z-direction displacement in the at least one distortion zone; and
forming the metal structures and the metal fill shapes on the substrate as the patterned metal layer.

2. The method of claim 1, further comprising:
directly bonding a dielectric material of the patterned metal layer of the substrate to an additional substrate to from a bonded substrate structure.

3. The method of claim 2, further comprising:
calculating bond strength of the substrate based on the design pattern and the fill pattern; and
adjusting surface area of the metal fill shapes to increase bond strength before forming the patterned metal layer.

4. The method of claim 1, further comprising:
calculating a Z-displacement map of the substrate based on the design pattern, the at least one distortion zone being identified using the Z-displacement map;
calculating a corrected Z-displacement map of the substrate based on the design pattern and the fill pattern; and
repeating the steps of identifying at least one distortion zone, inserting metal fill shapes, and calculating the corrected Z-displacement map until a predetermined Z-displacement criterion is satisfied before forming the metal structures and the metal fill shapes on the substrate.

5. The method of claim 4, wherein repeating the steps further comprises:
calculating at least one long-range corrected Z-displacement map of the substrate based on the design pattern and the fill pattern using a first window size, the corrected Z-displacement map being a short-range corrected Z-displacement map calculated using a second window size smaller than the first window size.

6. The method of claim 4, wherein calculating the Z-displacement map and calculating the corrected Z-displacement map comprise calculating Z-displacement of the substrate due to thermal stress.

7. The method of claim 1, further comprising:
inserting additional metal fill shapes in the fill pattern to reduce Z-direction displacement of the substrate in additional distortion zones of the at least one distortion zone.

8. A method of forming a bonded substrate structure, the method comprising:
calculating bond strength of a substrate based on a design pattern of metal structures and a fill pattern of metal fill shapes;
adjusting surface area of the metal fill shapes to increase the bond strength;
forming the metal structures and the metal fill shapes on the substrate as a patterned metal layer; and
directly bonding a dielectric material of the patterned metal layer of the substrate to an additional substrate to form the bonded substrate structure.

9. The method of claim 8, further comprising:
identifying at least one distortion zone in the design pattern causing a Z-direction displacement of the substrate;
inserting the metal fill shapes as the fill pattern into the design pattern to reduce the Z-direction displacement in the at least one distortion zone.

10. The method of claim 8,
wherein calculating the bond strength comprises
calculating localized bond strength in windows across the substrate, and
wherein adjusting the surface area comprises
adjusting the surface area of the metal fill shapes for each of the windows to increase uniformity of the bond strength across the substrate.

11. The method of claim 8,
wherein directly bonding the substrate to the additional substrate is a fusion bonding process, and
wherein adjusting the surface area of the metal fill shapes comprises
decreasing the surface area of the metal fill shapes.

12. The method of claim 8,
wherein directly bonding the substrate to the additional substrate further comprises directly bonding metal material of the patterned metal layer of the substrate to the additional substrate in a hybrid bonding process, and
wherein adjusting the surface area of the metal fill shapes comprises
increasing the surface area of the metal fill shapes.

13. The method of claim 8, wherein the substrate is a die and the additional substrate is a wafer.

14. The method of claim 8, wherein the substrate is a wafer and the additional substrate is an additional wafer.

15. A method of forming a bonded substrate structure, the method comprising:
identifying at least one distortion zone in a design pattern of metal structures causing a Z-direction displacement of a substrate;
inserting metal fill shapes as a fill pattern into the design pattern to reduce the Z-direction displacement in the at least one distortion zone;
calculating bond strength of the substrate based on the design pattern and the fill pattern;
adjusting surface area of the metal fill shapes to increase the bond strength;
forming the metal structures and the metal fill shapes on the substrate as a patterned metal layer; and
directly bonding a dielectric material of the patterned metal layer of the substrate to an additional substrate to form the bonded substrate structure.

16. The method of claim 15, further comprising:
calculating a Z-displacement map of the substrate based on the design pattern, the at least one distortion zone being identified using the Z-displacement map;
calculating a corrected Z-displacement map of the substrate based on the design pattern and the fill pattern; and
repeating the steps of identifying at least one distortion zone, inserting metal fill shapes, calculating the corrected Z-displacement map, calculating the bond strength, and adjusting the surface area until a predetermined co-optimization criterion is satisfied before forming the metal structures and the metal fill shapes on the substrate.

17. The method of claim 16, wherein the substrate is a die and the additional substrate is a wafer, and wherein the predetermined co-optimization criterion prioritizes increasing bond strength.

18. The method of claim 16, wherein the substrate is a wafer and the additional substrate is an additional wafer, and wherein the predetermined co-optimization criterion prioritizes reducing Z-direction displacement.

19. The method of claim 15,
wherein directly bonding the substrate to the additional substrate is a fusion bonding process, and
wherein adjusting the surface area of the metal fill shapes comprises
decreasing the surface area of the metal fill shapes.

20. The method of claim 15,
wherein directly bonding the substrate to the additional substrate further comprises directly bonding metal material of the patterned metal layer of the substrate to the additional substrate in a hybrid bonding process, and
wherein adjusting the surface area of the metal fill shapes comprises
increasing the surface area of the metal fill shapes.
